(19) United States
(12) Patent Application Publication
(10) Pub. No.: US 2024/0321788 A1
(43) Pub. Date: Sep. 26, 2024

(54) PAD AND PACKAGE INCLUDING SAME

(71) Applicant: SAMSUNG ELECTRONICS CO., LTD., Suwon-si (KR)

(72) Inventor: Wenjun WANG, Suzhou Industrial Park (CN)

(73) Assignee: SAMSUNG ELECTRONICS CO., LTD., Suwon-si (KR)

(21) Appl. No.: 18/439,349

(22) Filed: Feb. 12, 2024

(30) Foreign Application Priority Data
Mar. 24, 2023 (CN) 202310301066.3

(51) Int. Cl. H01L 23/00; H04N 23/52

(52) U.S. Cl. CPC H01L 24/05; H01L 24/08; H01L 24/16; H01L 2224/0401; H01L 2224/05557; H01L 2224/0807; H01L 2224/16014; H01L 2224/16227; H01L 2924/3512; H01L 2924/3841

(57) ABSTRACT

A pad includes a terminal portion having a first surface and a second surface opposite to the first surface; and a curved concave portion formed in one of the first surface and the second surface, wherein the curved concave portion is configured to clad a portion of a connecting conductor.

### CROSS-REFERENCE TO RELATED APPLICATION

This application is based on and claims priority under 35 U.S.C. § 119 to Chinese Patent Application No. 202310301066.3, filed on Mar. 24, 2023, in the China National Intellectual Property Administration, the disclosure of which is incorporated by reference herein in its entirety.

### BACKGROUND

### 1. Field

The present disclosure relates to chip packaging, and in particular, to a pad and a package including the same.

### 2. Description of the Related Art

Chip packaging for a camera may include chip-on-board (COB) packaging, flip-chip packaging, and the like. In COB packaging, pads of a sensor chip and pads of a substrate are electrically connected to each other by metal conductors through a wire bonding (WB) process. The metal conductors may generally include gold wires. In flip-chip packaging, pads of a sensor chip and pads of a substrate are electrically connected to each other by solder balls through a stamp ball bonding (SBB) process. The solder balls may include gold balls.

Generally, during a process of producing a camera, in order to ensure reliability of a product, after the camera is packaged, a series of reliability tests, such as a high-temperature and high-humidity environment test, a temperature impact test and a drop test, are required to ensure that the product can operate normally and stably under different environmental conditions. Currently, in a reliability test of the camera, an open circuit failure between a sensor chip and a package substrate is a functional failure with a highest failure rate among functional failures. It has been found that connecting wires between the sensor chip and the package substrate may crack at the pads, which may cause an open circuit. The open circuit between the sensor chip and the package substrate may cause the camera products to be scrapped. Accordingly, it is important to conduct research about improving the reliability of chip packaging.

Besides the open failure, there is also a short failure sometimes due to the overflow issue in the package. In COB packaging and flip-chip packaging, chip packaging for a camera is essentially a welding process. FIG. 1 is a schematic view showing a structure of a sensor chip in the related art. FIG. 2 is a cross-sectional view showing the structure of the sensor chip in FIG. 1. FIG. 3 is a cross-sectional view showing a package formed by bonding the sensor chip of FIG. 1 to a substrate using a flip-chip packaging method. As shown in FIGS. 1 and 2, the sensor chip in the related art includes a chip body 20 and pads (chip pads) 201 formed on the chip body 20. The pads 201 have a rectangular planar (plate) structure. In the package formed after soldering, as shown in FIG. 3, the pads 201 of the sensor chip and pads (substrate pads) 101 of a substrate 10 are electrically connected to each other via solder balls 30. The pads 101 have a rectangular planar (plate) structure. A contact surface (solder joint) between the solder balls 30 and the pads 201 is generally circular, and the solder balls 30 easily overflow the pads due to the pads 201 having the planar structure. When adjacent solder balls contact with each other due to overflow, a short circuit failure easily occurs.

### SUMMARY

Example embodiments relate to a pad capable of increasing a contacting area between a connecting conductor and the pad, thereby improving the reliability of chip packaging, and a package including the same.

According to an aspect of an example embodiment, a pad includes: a terminal portion having a first surface and a second surface opposite to the first surface; and a curved concave portion formed in one of the first surface and the second surface to clad a portion of a connecting conductor.

According to an aspect of an example embodiment, a package includes: a substrate including a first connection area; a chip body including a second connection area; a substrate pad disposed on the first connection area; a chip pad disposed on the second connection area; and a connecting conductor connecting the substrate pad and the chip pad, wherein the chip pad includes: a terminal portion having a first surface and a second surface opposite to the first surface; and a first curved concave portion formed in one of the first surface and the second surface, wherein the first curved concave portion clads a first portion of the connecting conductor.

According to an aspect of an example embodiment, an apparatus includes: a first pad comprising a first concave surface configured to wrap around a connecting conductor.

### BRIEF DESCRIPTION OF THE DRAWINGS

The above and other aspects and features will be more apparent from the following description of example embodiments, taken in conjunction with the accompanying drawings, in which:

FIG. 1 is a schematic view showing a structure of a sensor chip in the related art;

FIG. 2 is a cross-sectional view showing the structure of the sensor chip in

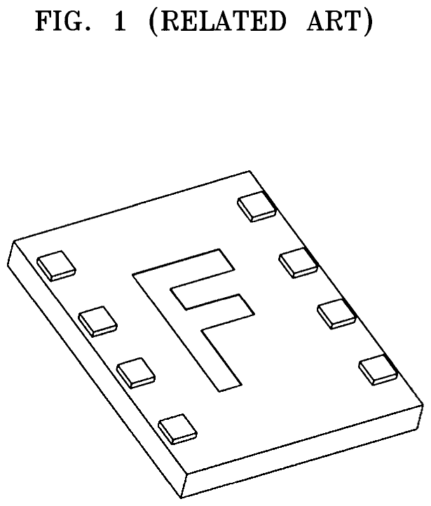

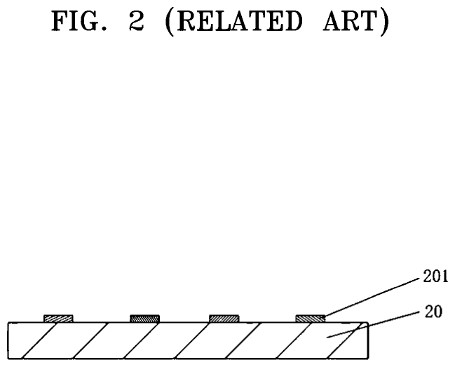

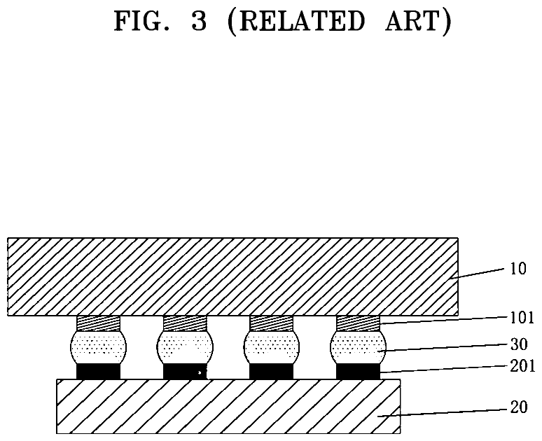

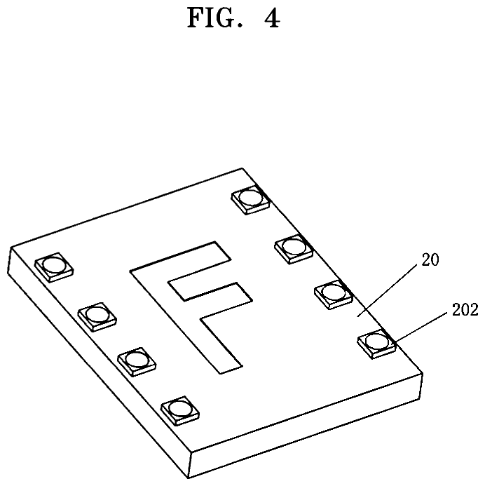

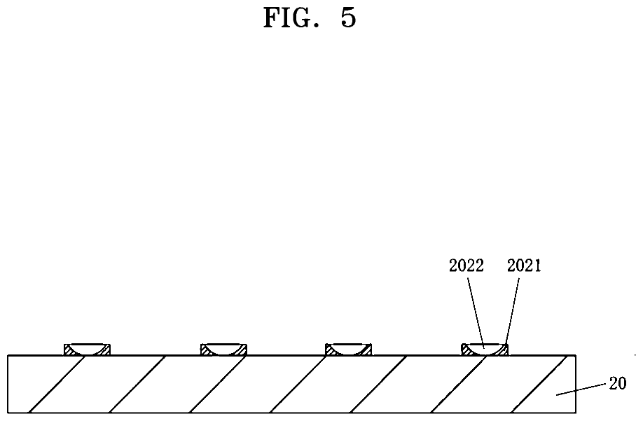

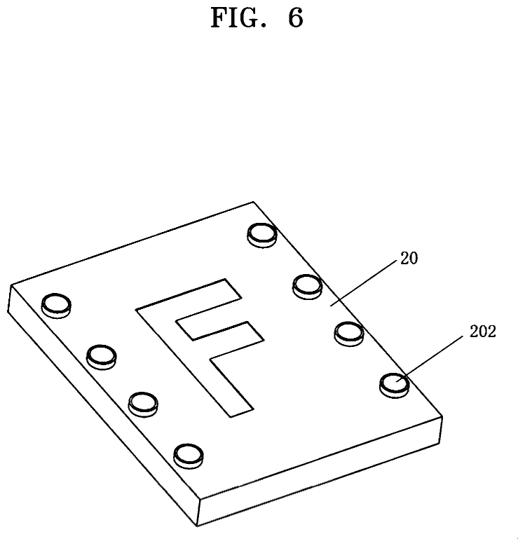

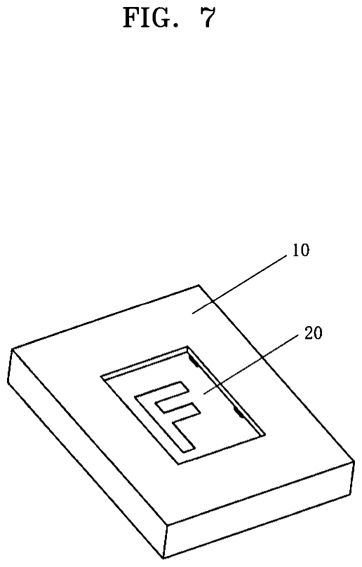

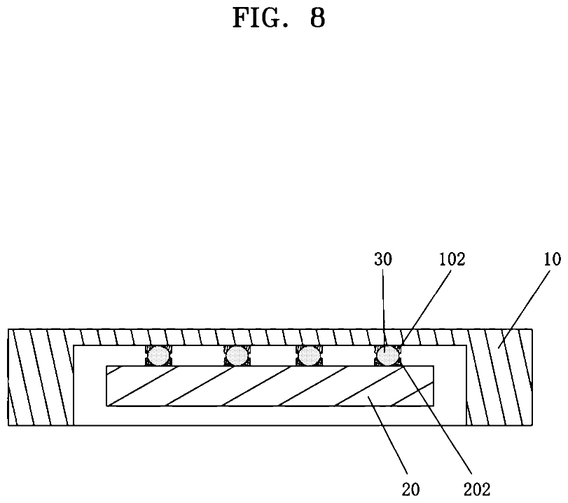

FIG. 1;

FIG. 3 is a cross-sectional view showing a package formed by bonding the sensor chip of FIG. 1 to a substrate using a flip-chip packaging method;

FIG. 4 is a schematic view showing a structure of a sensor chip according to an example embodiment;

FIG. 5 is a cross-sectional view showing the structure of the sensor chip in FIG. 4 according to an example embodiment;

FIG. 6 is a schematic view showing a structure of a sensor chip according to another example embodiment;

FIG. 7 is a schematic view showing a package formed by bonding the sensor chip of FIG. 4 to a substrate using a flip-chip packaging method according to an example embodiment; and

FIG. 8 is a cross-sectional view showing the package formed by bonding the sensor chip of FIG. 4 to the substrate using a flip-chip packaging method according to an example embodiment.

### DETAILED DESCRIPTION

Hereinafter, example embodiments will be described more fully with reference to the accompanying drawings, in which example embodiments are shown. Embodiments described herein are provided as examples, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

In the drawings, sizes of elements, layers and regions may be exaggerated for clarity. For ease of description, spatially relative terms, such as “beneath” “below” “lower” “under” “above” “upper” and the like, may be used herein to describe one element or feature's relationship to another element(s) or feature(s) as illustrated in the drawings. It will be understood that the spatially relative terms may also encompass different orientations of a device in use or operation in addition to the orientation depicted in the drawings. For example, if the device in the drawings is turned over, elements described as “below”, “beneath” or “under” another element or feature would then be oriented “above” the other element or feature. Thus, the example term “below” and “under” can encompass both orientations of “above” and “below”. The device may be otherwise oriented (e.g., rotated 90 degrees or at other orientations), and the spatially relative descriptors used herein should be interpreted accordingly.

Hereinafter, a chip pad according to an example embodiment will be described in more detail with reference to the drawings.

FIG. 4 is a schematic view showing a structure of a sensor chip according to an example embodiment. FIG. 5 is a cross-sectional view showing the structure of the sensor chip in FIG. 4. FIG. 6 is a schematic view showing a structure of a sensor chip according to another example embodiment.

Referring to FIGS. 4 and 5, a sensor chip may include a chip body 20 and pads (also referred to as chip pads) 202 disposed on the chip body 20. The chip body 20 may include a first connection area, and the pads 202 may be disposed on the first connection area. The chip body 20 may be any one of image sensor chip bodies commonly used in imaging devices of electronic products in the art. The pads 202 may include, for example, a common metal conductor material capable of conducting electricity, such as gold, silver, copper, etc.

The pads 202 may include a terminal portion 2021 and a curved concave portion 2022. The curved concave portion 2022 may include a curved surface. The terminal portion 2021 may include a first surface (e.g., an upper surface) and a second surface (e.g., a lower surface) opposite to each other in a thickness direction thereof, and the curved concave portion 2022 may be formed in one of the first surface and the second surface (for example, in the upper surface). That is, one of the first surface and the second surface is a concave surface. Specifically, the curved concave portion 2022 may be formed in one of the first surface and the second surface that is not in contact with the chip body 20.

Referring to FIG. 5, in a cross-sectional view, the curved concave portion 2022 may be a cambered surface. In an example embodiment, the curved concave portion 2022 may have the same curvature radius or a varying curvature radius. For example, the curved concave portion 2022 may have a concave spherical surface or a concave ellipsoidal surface. However, embodiments are not limited thereto, and the curved concave portion 2022 may have various other concave shapes.

According to an example embodiment, the terminal portion 2021 may have a cube shape, a cuboid shape, a prism shape other than a cube shape and a cuboid shape or a cylindrical shape. The curved concave portion 2022 may be formed at a central portion of the surface of the terminal portion 2021. In the example embodiment of the chip body 20 as shown in FIG. 4, the terminal portion 2021 has a cube shape, the curved concave portion 2022 has a concave spherical surface, and the curved concave portion 2022 is formed at the central portion of the surface of the terminal portion 2021 in a form of an inscribed sphere. In the example embodiment of the chip body 20 as shown in FIG. 6, the terminal portion 2021 has a cylindrical shape, the curved concave portion 2022 has a concave spherical surface, and the curved concave portion 2022 is formed at the central portion of the surface of the terminal portion 2021 in a form of a concentric axis.

Referring to FIG. 5, according to an example embodiment, a depth of the curved concave portion 2022 may be smaller than a height of the terminal portion 2021. However, embodiments are not limited thereto, and the depth of the curved concave portion 2022 may be equal to the height of the terminal portion 2021.

In an example embodiment, the pads 202 may be manufactured by a method commonly used in the art, such as an etching method. Specifically, the terminal portion 2021 may be first prepared, and then one surface of the terminal portion 2021 may be etched by the etching method (for example, dry etching or wet etching) to form the curved concave portion 2022, thereby forming the pads 202.

According to the example embodiment, by using a pad having a curved concave portion, a contacting area between a connecting conductor (such as a solder ball) and the pad may be increased, thereby improving the connection strength. A likelihood of an open circuit failure may be reduced or avoided due to the improving connection strength. Besides, the pads having the curved concave portions may have a “wrapping” effect (that is, the curved concave portions of the pads may cover/clad/wrap portions of the connecting conductors to be located thereon), which can not only improve the connection strength, but may also reduce or avoid a likelihood of short circuit failure caused by the overflowing of solder balls. As a result, the reliability of a chip packaging may be improved. In addition, by using the pads (such as the chip pads) having curved concave portions, the connecting conductors may sink into the curved concave portions. Therefore, an overall package height of the chip may be reduced to a certain extent, which is beneficial to the ultra-thin and small-sized chip packaging.

Hereinafter, a package according to an example embodiment will be described in more detail with reference to the drawings.

FIG. 7 is a schematic view showing a package formed by bonding the sensor chip of FIG. 4 to a substrate using a flip-chip packaging method according to an example embodiment. FIG. 8 is a cross-sectional view showing the package formed by bonding the sensor chip of FIG. 4 to the substrate using the flip-chip packaging method according to an example embodiment.

In an example embodiment, referring to FIGS. 7 and 8, a package may include a substrate 10, pads (also referred to as substrate pads) 102 disposed on the substrate 10, a chip body 20, and pads 202 disposed on the chip body 20. The pads 102 and the pads 202 may be electrically connected to each other by connecting conductors 30. The substrate 10 may be any one of substrates commonly used in imaging devices of electronic products in the art. The pads 202 may include a metal material capable of conducting electricity, such as gold, silver, copper, etc. The connecting conductors 30 may include solder balls 30. However, embodiments are not limited thereto, and the connecting conductors 30 may also include bonding wires.

The substrate 10 may include a second connection area, and the pads 102 may be disposed on the second connection area. The pads 102 may have substantially the same configuration as that of the pads 202 described above. Specifically, the pads 102 may include a terminal portion and a curved concave portion. The terminal portion may include a first surface and a second surface opposite to each other, and the curved concave portion may be formed in a surface of the first surface and the second surface facing the pads 202. In an example embodiment, the curved concave portion may have a concave spherical surface or a concave ellipsoidal surface, and the terminal portion may have a cube shape, a cuboid shape, or a cylindrical shape. However, embodiments are not limited thereto. The curved concave portion may have various other concave shapes in addition to the concave spherical surface and the concave ellipsoidal surface, and the terminal portion may have other prismatic shapes in addition to the cube shape and the cuboid shape. Generally, the curved concave portion may be formed at a central portion of the surface of the terminal portion.

In the package of an example embodiment, the pads 102 and the pads 202 may both have curved concave portions which may expand accommodation spaces of the pads, and may face each other to form a cladding cavity (see FIG. 8). Accordingly, the two opposite pads 102 and 202 may have a “wrapping” effect. The cladding cavity may completely clad the connecting conductor 30 therein. However, an example embodiment is not limited thereto, and the cladding cavity may partially clad the connecting conductor 30. In an example embodiment, by cladding the connecting conductor 30 with the cladding cavity formed by the curved concave portions of the two opposite pads 102 and 202, it is possible to prevent the connecting conductor 30 from overflowing the pads, and to reduce or avoid a likelihood of the short circuit failure caused by the overflowing contact of adjacent connecting conductors 30. In addition, the connection strength of the connecting conductor 30 may be improved by cladding the connecting conductor 30 with the cladding cavity, so as to reduce or avoid a likelihood of the open circuit failure.

In an example embodiment, the pads 102 and 202 may have the same size as each other. That is, the pads 102 and 202 may have curved concave portions with the same size as each other. In this case, the pads 102 clad one portion of the connecting conductor 30, and the pads 202 clad another portion of the connecting conductor 30. A volume of the one portion of the connecting conductor 30 may be the same as that of the other portion of the connecting conductor 30. In another example embodiment, the pads 102 and 202 may have curved concave portions with different sizes from each other. In this case, the pads 102 clad one portion of the connecting conductor 30, and the pads 202 clad another portion of the connecting conductor 30. A volume of the one portion of the connecting conductor 30 may be different from that of the other portion of the connecting conductor 30. Alternatively, a volume of the portion of the connecting conductor 30 clad by the pads 202 may be larger than that of the portion of the connecting conductor 30 clad by the pads 102, and in this case, a coating body with a stable structure may be formed.

In another example embodiment, rectangular planar pads in the related art shown in FIG. 3 may be used instead of the pads 102 described above.

An example embodiment provides a pad having a curved concave portion. By using the pad having the curved concave portion, a contacting area between a connecting conductor and the pad may be increased, thereby improving the connection strength. Accordingly, the reliability of a chip packaging may be improved, and a likelihood of the open circuit failure may be reduced or avoided. In addition, by using the pad (such as the chip pad) having the curved concave portion, the connecting conductor may sink into the curved concave portion. Therefore, an overall package height of the chip may be reduced to a certain extent, which is beneficial to the ultra-thin and small-sized chip packaging.

An example embodiment provides a package. The package has a chip pad and a substrate pad both including curved concave portions which may expand accommodation spaces of the pads. When being soldered, the pads facing each other may form a cladding cavity (thereby having a “wrapping” effect). By cladding the connecting conductor with the cladding cavity, it is possible to prevent the connecting conductor from overflowing the pads, and to reduce or avoid a likelihood of the short circuit failure caused by the overflowing contact of adjacent connecting conductors. In addition, the connection strength of a connecting conductor may be improved by cladding the connecting conductor with the cladding cavity, so as to reduce or avoid a likelihood of the open circuit failure.

It should be understood that example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the claims.

What is claimed is:

1. A pad comprising:
a terminal portion having a first surface and a second surface opposite to the first surface; and
a curved concave portion formed in one of the first surface and the second surface,
wherein the curved concave portion is configured to clad a portion of a connecting conductor.

2. The pad as claimed in claim 1, wherein the curved concave portion has a concave spherical surface or a concave ellipsoidal surface.

3. The pad as claimed in claim 1, wherein the terminal portion has a prism shape or a cylindrical shape.

4. The pad as claimed in claim 1, wherein the curved concave portion has a depth less than or equal to a height of the terminal portion.

5. A package comprising:
a substrate comprising a first connection area;
a chip body comprising a second connection area;
a substrate pad disposed on the first connection area;
a chip pad disposed on the second connection area; and
a connecting conductor connecting the substrate pad and the chip pad,
wherein the chip pad comprises:
a first terminal portion having a first surface and a second surface opposite to the first surface; and
a first curved concave portion formed in one of the first surface and the second surface, and
wherein the first curved concave portion clads a first portion of the connecting conductor.

6. The package as claimed in claim 5, wherein the substrate pad comprises:
a second terminal portion having a third surface and a fourth surface opposite to the third surface; and
a second curved concave portion formed in one of the third surface and the fourth surface,
wherein the second curved concave portion clads a second portion of the connecting conductor.

7. The package as claimed in claim 5, wherein the connecting conductor comprises a solder ball.

8. The package as claimed in claim 6, wherein the substrate pad and the chip pad form a cladding cavity, and
wherein the cladding cavity completely clads the connecting conductor.

9. The package as claimed in claim 6, wherein the substrate pad and the chip pad form a cladding cavity, and
wherein the cladding cavity partially clads the connecting conductor.

10. The package as claimed in claim 6, wherein a volume of the first portion of the connecting conductor is the same as a volume of the second portion of the connecting conductor.

11. The package as claimed in claim 6, wherein a volume of the first portion of the connecting conductor is different from a volume of the second portion of the connecting conductor.

12. The package as claimed in claim 6, wherein the package is configured as chip packaging for a camera.

13. An apparatus comprising:
a first pad comprising a first concave surface configured to wrap around a connecting conductor.

14. The apparatus of claim 13, further comprising a second pad comprising a second concave surface configured to wrap around the connecting conductor,
wherein the first concave surface faces toward the second concave surface.

15. The apparatus of claim 14, further comprising a chip body,
wherein the first pad is disposed on the chip body.

16. The apparatus of claim 15, further comprising a substrate,
wherein the second pad is disposed on the substrate.

17. The apparatus of claim 16, further comprising the connecting conductor disposed between the first pad and the second pad.

18. The apparatus of claim 17, wherein the connecting conductor comprises a convex surface.

19. The apparatus of claim 13, wherein the apparatus is configured as chip packaging for a camera.
